(19) United States
(12) Patent Application Publication
(10) Pub. No.: US 2009/0025636 A1
(43) Pub. Date: Jan. 29, 2009

(54) HIGH PROFILE MINIMUM CONTACT PROCESS KIT FOR HDP-CVD APPLICATION

(75) Inventor: MUHAMMAD RASHEED, Fremont, CA (US)

Correspondence Address: TOWNSEND AND TOWNSEND AND CREW LLP, TWO EMBARCADERO CENTER, EIGHTH FLOOR, SAN FRANCISCO, CA, 94111-3834, US

(73) Assignee: Applied Materials, Inc., Santa Clara, CA (US)

(21) Appl. No.: 11/829,341

(22) Filed: Jul. 27, 2007

(51) Int. Cl. H01L 21/683

(52) U.S. Cl. 118/500

(57) ABSTRACT

A process kit cover for chemical vapor deposition processes is disclosed according to one embodiment of the invention. The process kit cover may include a protrusion from the top surface of the process kit cover. The protrusion is adjacent to a wafer facing surface. The protrusion decreases oxide buildup on the process kit cover and the wafer facing surface during repeated deposition processes. The process kit cover may also be in minimal thermal contact at the interface with a lower support structure, such as a ceramic collar or pedestal, according to another embodiment of the invention. Minimal thermal contact may be achieved by placing an insulator between the process kit cover and the lower support structure or by creating a gap or gaps between the process kit cover and the lower support structure. Ambient atmosphere may provide thermal insulating within the gap or gaps.

### BACKGROUND OF THE INVENTION

One of the primary steps in the fabrication of modern semiconductor devices is the formation of a thin film on a semiconductor wafer by chemical reaction of gases. Such a deposition process is referred to as chemical vapor deposition (“CVD”). Conventional thermal CVD processes supply reactive gases to the wafer surface where heat-induced chemical reactions take place to produce a desired film. Plasma-enhanced CVD (“PECVD”) techniques, on the other hand, promote excitation and/or dissociation of the reactant gases by the application of radio-frequency (“RF”) energy to a reaction zone near the wafer surface, thereby creating a plasma. The high reactivity of the species in the plasma reduces the energy required for a chemical reaction to take place and, thus, lowers the temperature required for such CVD processes as compared to conventional thermal CVD processes. These advantages are further exploited by high-density-plasma (“HDP”) CVD techniques, in which a dense plasma is formed at low vacuum pressures so that the plasma species are even more reactive.

In some CVD applications, a wafer is supported within a process chamber by a process kit 100 as shown in FIGS. 2 and 3. During various plasma deposition processes, oxide powder buildup 150 can accumulate on the process kit 100 near the edge of the wafer 120 as shown in FIGS. 2 and 3. Oxide powder buildup 150 may increase with increased repetitions. Increased oxide powder buildup can lead to unsatisfactory wafer bevel peeling, residue buildup, as well as process and buffer chamber contamination.

In view of the above problems that persist with prior-art process kit covers, new and improved process kit covers are desirable.

### BRIEF SUMMARY OF THE INVENTION

A wafer support structure is disclosed according to one embodiment of the invention. The wafer support structure includes a circular ring that substantially circumscribes a circular cavity. The circular ring is also generally concentric with the circular cavity. The circular ring may include a number of features. For example, the circular ring may be defined by an inner radius immediately circumscribing the circular cavity and an outer radius circumscribing the ring. The ring may also include top and bottom surfaces that are substantially perpendicular to the axis of the ring. The top and bottom surfaces are mostly parallel. However, some features of the top and bottom surfaces might not be parallel with each other. The top surface may include a wafer facing surface that extends circularly around the ring from the inner radius of the ring to a second radius. The wafer facing surface is designed to support a wafer during plasma CVD processes. The second radius is larger than and concentric with the inner radius of the ring yet smaller than the outer radius. The top surface includes a protrusion near the wafer facing surface that extends around the ring from the top surface of the ring in a direction substantially parallel to the axis. The protrusion is also located adjacent to the second radius on the top surface of the ring.

The protrusion on the wafer support structure may include a bevel at the intersection of the top surface of the protrusion and the side of the protrusion adjacent to the wafer facing surface. Moreover, the wafer facing surface may protrude approximately 0.03 to 0.1 inches from the top surface of the wafer support structure to the top surface of the protrusion measured along a line parallel to the axis of the ring.

A circular wafer may rest on the wafer facing surface. The radius of the wafer may be larger than the inner radius yet smaller than the second radius. The wafer support structure may be approximately 0.1 to 0.2 inches thick as measured from the bottom surface to the top surface along a line parallel to the axis of the ring. The wafer support structure may be made from a ceramic, such as, aluminum oxide.

The wafer support structure may include a thermal insulator proximate to at least a portion of the bottom surface of the ring. The thermal insulator may comprise an inert gas. The thermal insulator may also be a solid insulator. The inert gas may be the gas used within the chamber during CVD processes. The thermal insulator may include nitrogen, boron, argon, neon, and/or helium. The wafer support member may also include a thermal insulator proximate to at least a portion of the bottom surface of the ring. The insulator may provide thermal insulation between the circular ring and a ceramic collar.

A wafer processing system is also disclosed according to another embodiment of the invention. The wafer processing system may include a housing defining a process chamber, a high-density plasma generating system operatively coupled to the process chamber, a gas-delivery system configured to introduce gases into the process chamber, a pressure-control system for maintaining a selected pressure within the process chamber, and a wafer support member as described above.

### BRIEF DESCRIPTION OF THE DRAWINGS

FIG. 1 shows oxide buildup on a process kit.

FIG. 2 shows oxide buildup on another process kit.

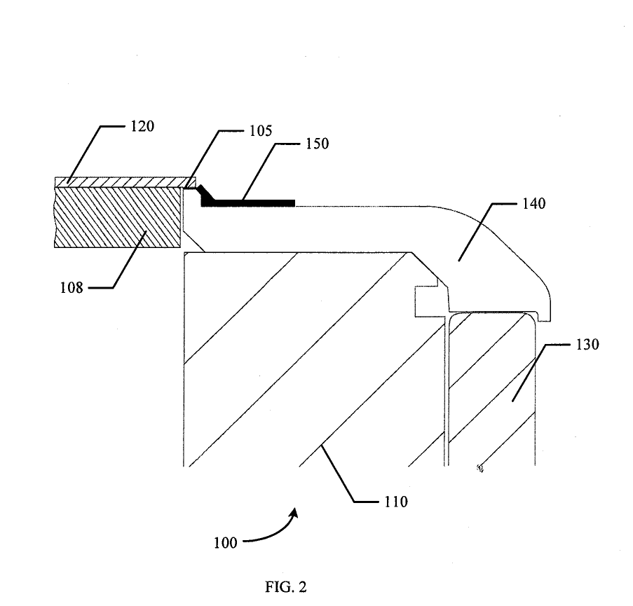

FIG. 3 shows a simplified diagram of one embodiment of a high-density plasma chemical vapor deposition system according to the present invention.

FIG. 4A shows a process kit cover with a high profile protrusion and a small contact surface according to one embodiment of the invention.

FIG. 4B shows a portion of a three-dimensional process kit cover with a high profile protrusion according to one embodiment of the invention.

FIG. 4C shows a top view of a portion of a process kit cover according to one embodiment of the invention.

FIG. 5 shows another process kit cover with a high profile protrusion and small contact surface according to one embodiment of the invention.

FIG. 6 shows a process kit cover with multiple minimum contact surface according to one embodiment of the invention.

FIG. 7 shows a process kit cover with a solid insulator between the process kit cover and a ceramic collar according to one embodiment of the invention.

In the appended figures, similar components and/or features may have the same reference label. Where the reference label is used in the specification, the description is applicable to any one of the similar components having the same reference label.

### DETAILED DESCRIPTION OF THE INVENTION

The ensuing description provides preferred exemplary embodiment(s) only, and is not intended to limit the scope, applicability or configuration of the disclosure. Rather, the ensuing description of the preferred exemplary embodiment(s) will provide those skilled in the art with an enabling description for implementing with an exemplary embodiment. It should be understood that various changes may be made in the function and arrangement of elements without departing from the spirit and scope as set forth in the appended claims.

In one embodiment, the present disclosure provides for a CVD process kit cover with a high profile feature. The process kit cover may be a generally circular ring-shaped structure. The high profile feature may be disposed over the process kit cover near a wafer facing surface. The wafer facing surface is disposed over the interior edge of the process kit cover. The high profile feature substantially surrounds a wafer when the wafer is placed on the wafer facing surface. A small clearance between the high profile feature and the wafer provides adequate space for a blade to remove the wafer. The high profile feature may decrease the amount of oxide buildup over time during CVD or other deposition processes.

In another embodiment of the invention, the present disclosure provides for a CVD process kit cover in small to no direct thermal contact with a lower support object or structure. The ceramic collar or structure may include a ceramic collar or other pedestal-like device that supports the process kit cover. The bottom surface of the process kit cover may include a thermal insulator. When the process kit is assembled, the insulator is in thermal communication with the lower support object or structure and provides thermal insulation. In one embodiment of the invention, only the insulator portion of the process kit cover is in direct contact with the lower support object or structure. In another embodiment, a portion of the bottom surface of the process kit cover and a thermal insulator or insulators are in direct contact with the lower support object or structure. The insulator allows the process kit cover to maintain high temperatures during the cleaning process, for example, during an NF₃-based clean. Without an insulator between the process kit cover and the lower support object or structure, heat may more easily transfer from the process kit cover to the lower support object or structure. The higher temperatures improve process kit cover cleaning.

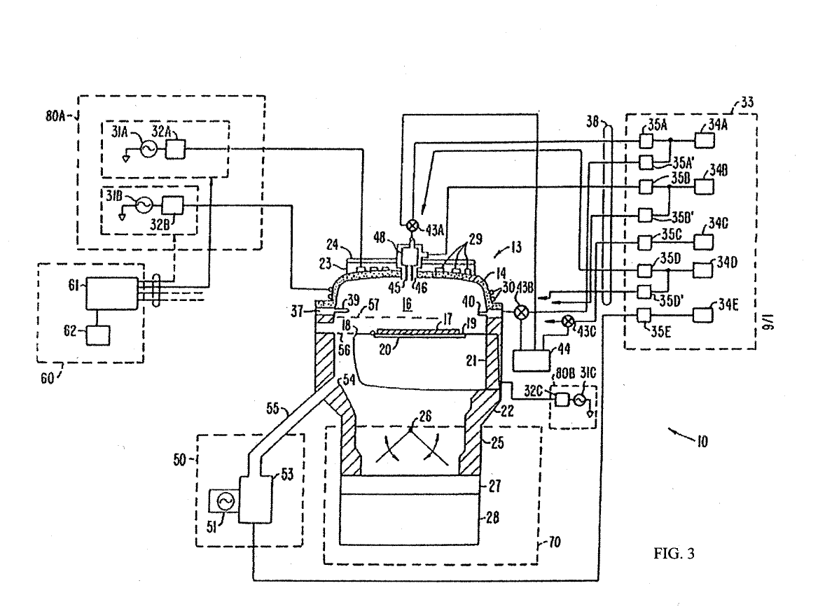

FIG. 3 illustrates one embodiment of a high density plasma chemical vapor deposition (HDP-CVD) system 10 in which a dielectric layer according to the present invention can be deposited. System 10 includes a chamber 13, a vacuum system 70, a source plasma system 80A, a bias plasma system 80B, a gas delivery system 33, and a remote plasma cleaning system 50.

The upper portion of chamber 13 includes a dome 14, which is made of a ceramic dielectric material, such as aluminum oxide or aluminum nitride. Dome 14 defines an upper boundary of a plasma processing region 16. Plasma processing region 16 is bounded on the bottom by the upper surface of a wafer 17 and a wafer support member 18.

A heater plate 23 and a cold plate 24 surmount, and are thermally coupled to, dome 14. Heater plate 23 and cold plate 24 allow control of the dome temperature to within about ±10° C. over a range of about 100° C. to 200° C. This allows optimizing the dome temperature for the various processes. For example, it may be desirable to maintain the dome at a higher temperature for cleaning or etching processes than for deposition processes. Accurate control of the dome temperature also reduces the flake or particle counts in the chamber and improves adhesion between the deposited layer and the wafer.

The lower portion of chamber 13 includes a body member 22, which joins the chamber to the vacuum system. A base portion 21 of wafer support member 18 is mounted on, and forms a continuous inner surface with, body member 22. Wafers are transferred into and out of chamber 13 by a robot blade (not shown) through an insertion/removal opening (not shown) in the side of chamber 13. Lift pins (not shown) are raised and then lowered under the control of a motor (also not shown) to move the wafer from the robot blade at an upper loading position 57 to a lower processing position 56 in which the wafer is placed on a wafer receiving portion 19 of wafer support member 18. Wafer receiving portion 19 includes an electrostatic chuck 20 that secures the wafer to wafer support member 18 during wafer processing. In a preferred embodiment, wafer support member 18 is made from an aluminum oxide or aluminum ceramic material.

Vacuum system 70 includes throttle body 25, which houses tri-blade throttle valve 26 and is attached to gate valve 27 and turbo-molecular pump 28. In some embodiments, a twin-blade or other multi-blade throttle valve 26 may be used. It should be noted that throttle body 25 offers minimum obstruction to gas flow and allows symmetric pumping. Gate valve 27 can isolate pump 28 from throttle body 25, and can also control chamber pressure by restricting the exhaust flow capacity when throttle valve 26 is fully open. The arrangement of the throttle valve, gate valve, and turbo-molecular pump allow accurate and stable control of chamber pressures from between about 1 millitorr to about 2 torr.

The source plasma system 80A includes a top coil 29 and side coil 30 mounted on dome 14. A symmetrical ground shield (not shown) reduces electrical coupling between the coils. Top coil 29 is powered by top source RF (SRF) generator 31A, whereas side coil 30 is powered by side SRF generator 31B, allowing independent power levels and frequencies of operation for each coil. This dual coil system allows control of the radial ion density in chamber 13, thereby improving plasma uniformity. Side coil 30 and top coil 29 are typically inductively driven, which does not require a complimentary electrode. In a specific embodiment, the top source RF generator 31A provides up to 2,500 watts of RF power at nominally 2 MHz and the side source RF generator 31B provides up to 5,000 watts of RF power at nominally 2 MHz. The operating frequencies of the top and side RF generators may be offset from the nominal operating frequency (e.g., to 1.7-1.9 MHz and 1.9-2.1 MHz, respectively) to improve plasma-generation efficiency.

A bias plasma system 80B includes a bias RF (“BRF”) generator 31C and a bias matching network 32C. The bias plasma system 80B capacitively couples wafer portion 17 to body member 22, which act as complimentary electrodes. The bias plasma system 80B serves to enhance the transport of plasma species (e.g., ions) created by the source plasma system 80A to the surface of the wafer. In a specific embodiment, bias RF generator provides up to 5,000 watts of RF power at 13.56 MHz.

RF generators 31A and 31B include digitally controlled synthesizers and operate over a frequency range between about 1.8 to about 2.1 MHz. Each generator includes an RF control circuit (not shown) that measures reflected power from the chamber and coil back to the generator and adjusts the frequency of operation to obtain the lowest reflected power, as understood by a person of ordinary skill in the art. RF generators are typically designed to operate into a load with a characteristic impedance of 50 ohms. RF power may be reflected from loads that have a different characteristic impedance than the generator. This can reduce power transferred to the load. Additionally, power reflected from the load back to the generator may overload and damage the generator. Because the impedance of a plasma may range from less than 5 ohms to over 900 ohms, depending on the plasma ion density, among other factors, and because reflected power may be a function of frequency, adjusting the generator frequency according to the reflected power increases the power transferred from the RF generator to the plasma and protects the generator. Another way to reduce reflected power and improve efficiency is with a matching network.

Matching networks 32A and 32B match the output impedance of generators 31A and 31B with their respective coils 29 and 30. The RF control circuit may tune both matching networks by changing the value of capacitors within the matching networks to match the generator to the load as the load changes. The RF control circuit may tune a matching network when the power reflected from the load back to the generator exceeds a certain limit. One way to provide a constant match, and effectively disable the RF control circuit from tuning the matching network, is to set the reflected power limit above any expected value of reflected power. This may help stabilize a plasma under some conditions by holding the matching network constant at its most recent condition.

Other measures may also help stabilize a plasma. For example, the RF control circuit can be used to determine the power delivered to the load (plasma) and may increase or decrease the generator output power to keep the delivered power substantially constant during deposition of a layer.

A gas delivery system 33 provides gases from several sources, 34A-34E chamber for processing the wafer via gas delivery lines 38 (only some of which are shown). As would be understood by a person of skill in the art, the actual sources used for sources 34A-34E and the actual connection of delivery lines 38 to chamber 13 vary depending on the deposition and cleaning processes executed within chamber 13. Gases are introduced into chamber 13 through a gas ring 37 and/or a top nozzle 45.

In one embodiment, first and second gas sources, 34A and 34B, and first and second gas flow controllers, 35A′ and 35B′, provide gas to ring plenum in gas ring 37 via gas delivery lines 38 (only some of which are shown). Gas ring 37 has a plurality of source gas nozzles 39 (only one of which is shown for purposes of illustration) that provide a uniform flow of gas over the wafer. Nozzle length, orifice and nozzle angle may be changed to allow tailoring of the uniformity profile and gas utilization efficiency for a particular process within an individual chamber. In a preferred embodiment, gas ring 37 has 12 source gas nozzles made from an aluminum oxide ceramic.

Gas ring 37 also has a plurality of oxidizer gas nozzles 40 (only one of which is shown) which, in a preferred embodiment, are co-planar with and shorter than source gas nozzles 39 and, in one embodiment, receives gas from body plenum. In some embodiments, it is desirable not to mix source gases and oxidizer gases before injecting the gases into chamber 13. In other embodiments, oxidizer gas and source gas may be mixed prior to injecting the gases into chamber 13 by providing apertures (not shown) between body plenum and gas ring plenum 36. In one embodiment, third and fourth gas sources, 34C and 34D, and third and fourth gas flow controllers, 35C and 35D′, provide gas to body plenum via gas delivery lines 38. Additional valves, such as 43B (other valves not shown), may shut off gas from the flow controllers to the chamber.

In embodiments where flammable, toxic, or corrosive gases are used, it may be desirable to eliminate gas remaining in the gas delivery lines after a deposition. This may be accomplished using a 3-way valve, such as valve 43B, to isolate chamber 13 from delivery line and to vent delivery line to vacuum foreline 44, for example. As shown in FIG. 3, other similar valves, such as 43A and 43C, may be incorporated on other gas delivery lines. Such 3-way valves may be placed as close to chamber 13 as practical, to minimize the volume of the unvented gas delivery line (between the 3-way valve and the chamber). Additionally, two-way (on-off) valves (not shown) may be placed between a mass flow controller (“MFC”) and the chamber or between a gas source and an MFC.

Chamber 13 may also have a top nozzle 45 and top vent 46. Top nozzle 45 and top vent 46 may allow independent control of top and side flows of the gases, which improves film uniformity and allows fine adjustment of the film's deposition and doping parameters. Top vent 46 is an annular opening around top nozzle 45. In one embodiment, first gas source 34A supplies source gas nozzles 39 and top nozzle 45. Source nozzle MFC 35A′ controls the amount of gas delivered to source gas nozzles 39 and top nozzle MFC 35A controls the amount of gas delivered to top gas nozzle 45. Similarly, two MFCs, 35B and 35B′, may be used to control the flow of oxygen to both top vent 46 and oxidizer gas nozzles 40 from a single source of oxygen, such as source 34B. The gases supplied to top nozzle 45 and top vent 46 may be kept separate prior to flowing the gases into chamber 13, or the gases may be mixed in top plenum 48 before they flow into chamber 13. Separate sources of the same gas may be used to supply various portions of the chamber.

A remote microwave-generated plasma cleaning system 50 is provided to periodically clean deposition residues from chamber components. The cleaning system includes a remote microwave generator 51 that creates a plasma from a cleaning gas source 34E (e.g., molecular fluorine, nitrogen trifluoride, other fluorocarbons or equivalents) in reactor cavity 53. The reactive species resulting from this plasma are conveyed to chamber 13 through cleaning gas feed port 54 via applicator tube 55. The materials used to contain the cleaning plasma (e.g., cavity 53 and applicator tube 55) must be resistant to attack by the plasma. The distance between reactor cavity 53 and feed port 54 should be kept as short as practical, since the concentration of desirable plasma species may decline with distance from reactor cavity 53. Generating the cleaning plasma in a remote cavity allows the use of an efficient microwave generator and does not subject chamber components to the temperature, radiation, or bombardment of the glow discharge that may be present in a plasma formed in situ. Consequently, relatively sensitive components, such as electrostatic chuck 20, do not need to be covered with a dummy wafer or otherwise protected, as may be required with an in situ plasma cleaning process. In one embodiment, this cleaning system is used to dissociate atoms of the etchant gas remotely, which are then supplied to the process chamber 13. In another embodiment, the etchant gas is provided directly to the process chamber 13. In still a further embodiment, multiple process chambers are used, with deposition and etching steps being performed in separate chambers.

In alternative embodiment of the invention, a remote plasma system (RPS), rather than the remote microwave-generated plasma cleaning system, may be provided to periodically clean deposition residues from chamber components. The RPS may be mounted on the top of the dome 14. The RPS may introduce ionized clean gas into the chamber through a conically-shaped top baffle that may be coaxial with the center of the wafer pedestal. A fluid channel may run through the center of the baffle to supply a precursor or carrier gas with a different composition than the precursor flowing down the outside directing surface of the baffle. For example, the channel at the center of the baffle may carry processing gas and the outside channel may carry gas for cleaning such as NF₃.

The outside surface of the baffle may be surrounded by a conduit that directs a reactive precursor from a reactive species generating system that is positioned over the deposition chamber. The conduit may be a straight circular tube with one end opening on the outside surface of baffle and the opposite end coupled to the reactive species generating system.

The RPS may generate the reactive species by exposing a more stable starting material to the plasma. For example, the starting material may be a mixture that includes molecular oxygen (or ozone). The exposure of this starting material to a plasma from the RPS causes a portion of the molecular oxygen to dissociate into atomic oxygen, a highly reactive radical species that will chemically react with an organo-silicon precursor (e.g., OMCTS) at much lower temperatures (e.g., less than 100° C.) to form a flowable dielectric on the wafer surface. Because the reactive species generated in the reactive species generating system are often highly reactive with other deposition precursors at even room temperature, they may be transported in an isolated gas mixture down conduit and dispersed into the reaction chamber by baffle before being mixed with other deposition precursors.

System controller 60 controls the operation of system 10. In a preferred embodiment, controller 60 includes a memory 62, such as a hard disk drive, a floppy disk drive (not shown), and a card rack (not shown) coupled to a processor 61. The card rack may contain a single-board computer (SBC) (not shown), analog and digital input/output boards (not shown), interface boards (not shown), and stepper motor controller boards (not shown). The system controller conforms to the Versa Modular European (“VME”) standard, which defines board, card cage, and connector dimensions and types. The VME standard also defines the bus structure as having a 16-bit data bus and 24-bit address bus. System controller 60 operates under the control of a computer program stored on the hard disk drive or through other computer programs, such as programs stored on a removable disk. The computer program dictates, for example, the timing, mixture of gases, RF power levels and other parameters of a particular process. The interface between a user and the system controller is via a monitor, such as a cathode ray tube (“CRT”) and a light pen.

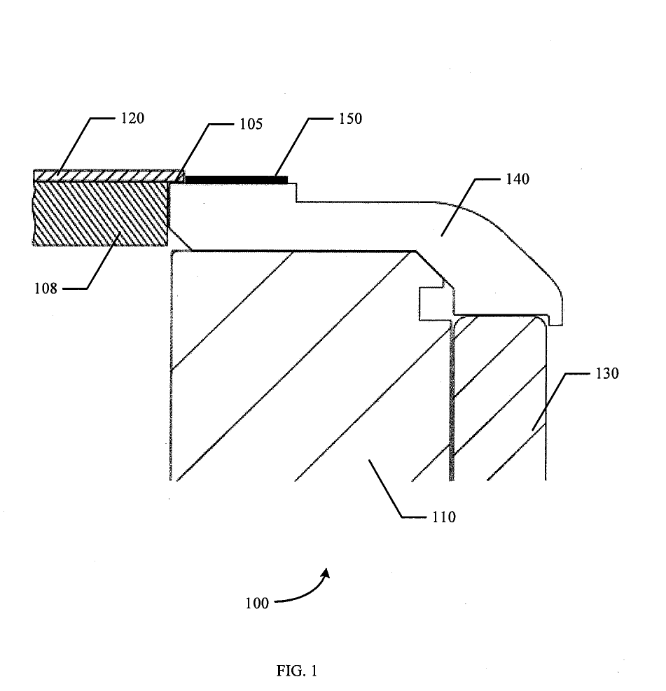

FIG. 1 is a cross-section of a portion of a vapor deposition process kit showing oxide buildup 150. The process kit 100 includes a process kit cover 140 that includes a wafer facing surface 105. A wafer 120 rests on a pedestal (or electro-static chuck) 108. The outer edge of the wafer 120 extends over the wafer facing surface 105 of the process kit cover 140. The wafer 120 is not is not in contact with the wafer facing surface 105. The process kit cover rests over a ceramic collar 110 that is surrounded by a bracket 130. Oxide buildup 150 occurs during repeat CVD processes. FIG. 1 shows another process kit 100 with oxide buildup 150. In both examples, oxide powder buildup occurs adjacent to the wafer 120 and, in some cases, occurs beneath the wafer 120 on the wafer facing surface 105.

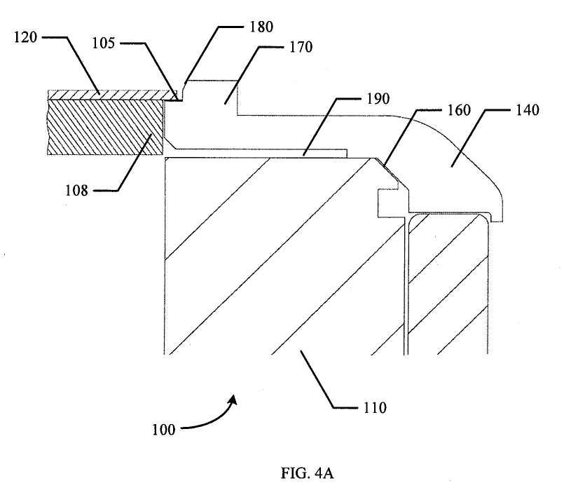

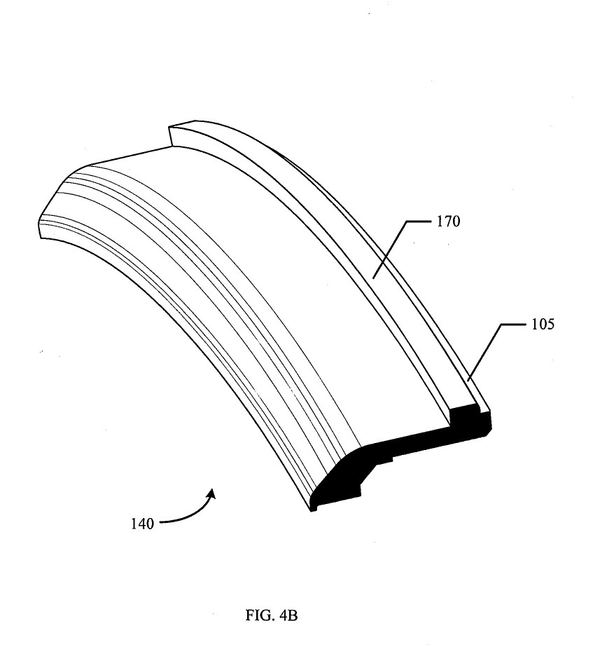

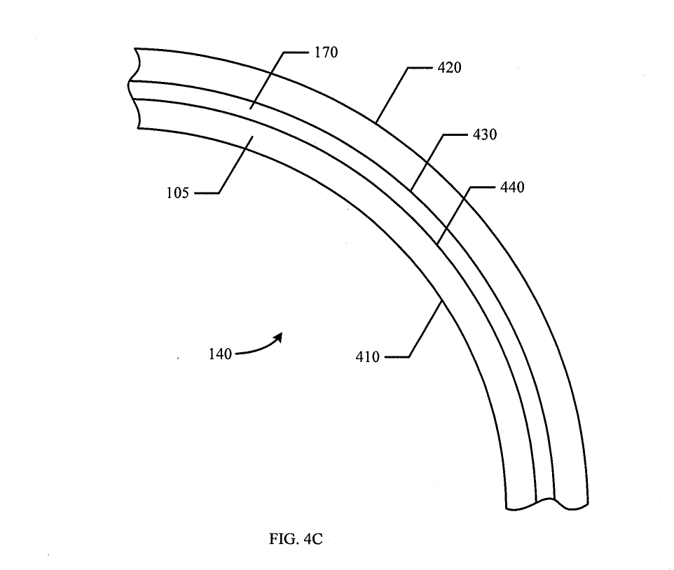

FIG. 4A shows a cross-section of a process kit 100 that includes a high profile feature 170 (or protrusion) that protrudes from the top surface of the process kit cover according to one embodiment of the invention. The high profile feature 170 may include a bevel 180 at the intersection of the top surface and the side surface nearest the wafer facing surface 105. The bevel may allow for a blade to retrieve the wafer 120. The high profile feature 170 may reduce oxide buildup adjacent to the wafer 120 and on the wafer facing surface 105.

The high profile feature 170, for example, may be between 0.02 inches and 0.12 inches high for a process kit that has an inner diameter between 11 inches and 13 inches, however the height of the high profile feature 170 may be any height. In another embodiment, the thickness-diameter ratio is between approximately 0.1 and 1. The gap between the wafer 120 and the high profile feature 170, for example, may be between 0.01 to 0.05 inches. The height of the high profile feature 170 from the top of the wafer 120 to the bottom of the bevel 180 may, for example, be from 0 to 5 times the thickness of the wafer 120. In one embodiment, the height of the high profile feature 170 from the top of the wafer 120 to the bottom of the bevel 180 may be 1 times to 2 times the thickness of the wafer 120. The width of the high profile feature 170 may be limited by a design constraint to keep the overall process kit cover material volume to a minimum.

Moreover, the process kit cover may be quite thin, for example, less than 0.25 inches. The thinness of the process kit cover 140 enables the process kit cover 140 to heat up during cleaning and, thus, increase the cleaning effectiveness. Both the process kit cover 140 and the high profile feature 170 may be constructed from a ceramic material. The high profile feature 170 may be integrated with the process kit cover 140 such that the two are part of a continuous piece. In another embodiment of the invention, the high profile feature 170 may be an add on feature that is made from the same or different material than the process kit cover 140. Moreover, the high profile feature 170 may be constructed separately and added to the process kit cover 140.

The process kit may also include an insulating gap 190. The insulating gap 190 limits the surface area over which the process kit cover 140 is in contact with a ceramic collar 110, such as, for example, a ceramic collar or a pedestal or other object. In this embodiment, the processing kit cover 140 is in partial contact with the ceramic collar 110 at an interface 160. The size of the interface 160 is minimized in order to minimize thermal conduction from the process kit cover 140 to the ceramic collar 110. In one embodiment of the invention, the interface 160 is approximately 0%-30% of the surface area of the bottom surface of the process kit cover 140. In another embodiment of the invention, the interface 160 is approximately 5%-25% of the surface area of the bottom surface of the process kit cover 140. According to another embodiment of the invention, the interface 160 is approximately 10%-20% of the surface area of the bottom surface of the process kit cover 140.

FIG. 4B shows a three-dimensional process kit cover 140 with the high profile feature 170 according to one embodiment of the invention. This three-dimensional figure also shows the circular shape of the process kit cover 140. Also shown is the wafer facing surface 105 of the circular process kit cover 140.

FIG. 4C shows a top view of a portion of a process kit cover 140 according to one embodiment of the invention. This figure is not drawn to scale. The figure shows a portion of a circular ring that makes up the process kit cover 140. The circular ring has an inner radius 410 and an outer radius 420. The inner radius 410 defines the interior of the ring and the outer radius 420 defines the exterior of the ring. The wafer facing surface 105 extends from the inner radius 410 to a second radius 430. The high profile feature 170 extends from the second radius 410 to a third radius 440.

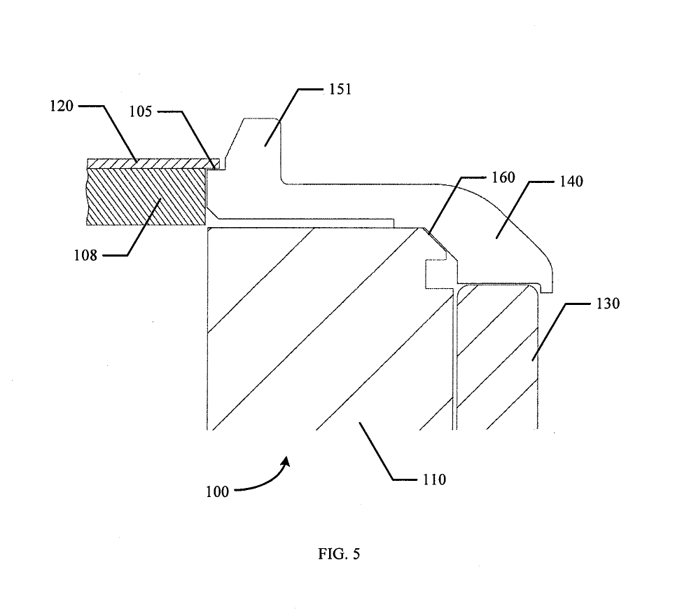

FIG. 5 shows another cross-section of portions of a process kit 100 with a high profile feature 151 according to another embodiment of the invention. In this embodiment, the high profile feature 151 protrudes higher from the process kit cover 140. Accordingly, the dimensionality of the high profile feature 151 is limited only by the vertical clearance above the process kit cover 140 and by allowing a blade to access the wafer 120 to lift the wafer 120 from the wafer facing surface 105. In this embodiment, the insulator is the atmosphere within the CVD, for example, reactive NF₃.

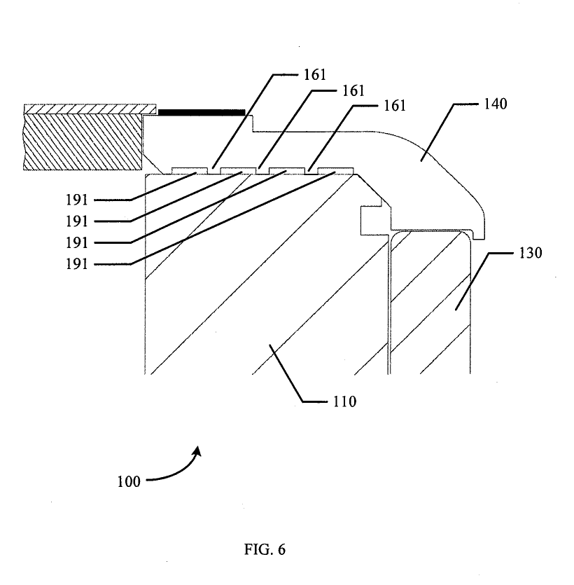

FIG. 6 shows another cross-section of portions of a process kit 100 according to another embodiment of the invention. In this embodiment, the process kit cover 140 includes multiple interfaces 161 with the ceramic collar 110. Insulators 191 are placed between the multiple interfaces 161. The insulators may be the atmosphere within the CVD chamber or a solid insulator. The interfaces may be larger or smaller than what is shown in the picture.

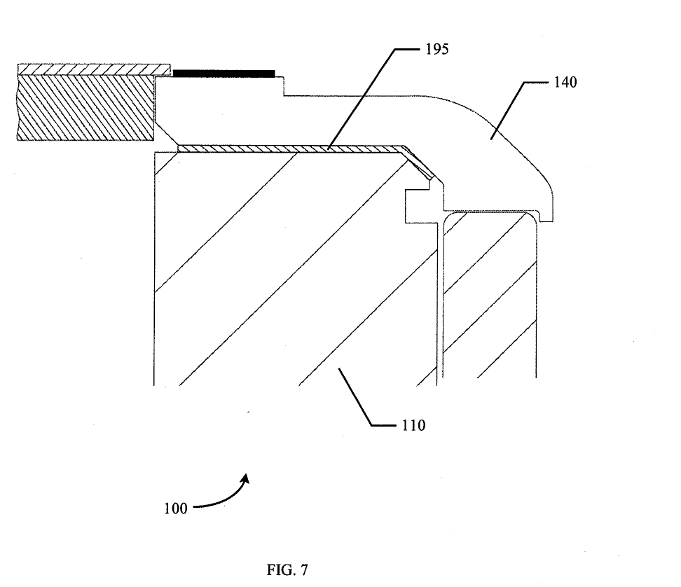

FIG. 7 shows another cross-section of portions of a process kit 100 according to another embodiment of the invention. According to this embodiment, the process kit cover 140 is completely thermally insulated from ceramic collar 110 within insulator 195. The insulator 195 in this embodiment may be a solid insulator. Any material with a lower thermal conductivity, for example, fiberglass, plastics, polymers, may be used as the insulator 195.

What is claimed is:

1. A wafer support structure comprising:
a circular ring substantially circumscribing a circular cavity and generally concentric with the circular cavity and, wherein the circular ring comprises:
an inner radius immediately circumscribing the circular cavity;
an outer radius circumscribing the ring;
a bottom surface having portions substantially perpendicular to the axis of the ring; and
a top surface having portions substantially perpendicular to the axis of the ring and substantially parallel to the bottom surface, and disposed opposite the bottom surface, wherein the top surface comprises:
a wafer facing surface extending circularly around the ring from the inner radius of the ring to a second radius, and perpendicular to the axis of the ring, wherein the second radius is larger than and concentric with the inner radius of the ring, and the second radius is smaller than the outer radius; and
a protrusion from the top surface extending around the ring, protruding in a direction substantially parallel to the axis of the ring, and adjacent to the second radius.

2. The wafer support structure of claim 1, wherein the protrusion comprises:
a protrusion top surface substantially parallel to the top surface of the ring;
an inner vertical surface perpendicular to and adjacent to the protrusion top surface and proximate to the second radius of the ring; and
a bevel at the intersection of the vertical surface and the protrusion top surface.

3. The wafer support structure of claim 1, wherein the protrusion protrudes approximately 0.03 to 0.1 inches from the top surface of the wafer support structure to the top surface of the protrusion measured along a line parallel to the axis of the ring.

4. The wafer support structure of claim 1, further comprising a circular wafer resting on the wafer facing surface, wherein the radius of the wafer is greater than the inner radius of the ring and less than the second radius of the ring.

5. The wafer support structure of claim 1, wherein the wafer support structure is approximately 0.1 to 0.2 inches thick as measured from the bottom surface of the wafer support structure to the top surface of the wafer support structure as measured along a line parallel to the axis of the ring.

6. The wafer support structure of claim 1, wherein the wafer support structure comprises ceramic.

7. The wafer support structure of claim 1, wherein the wafer support structure comprises aluminum oxide.

8. The wafer support structure of claim 1, further comprising a thermal insulator proximate to at least a portion of the bottom surface of the ring.

9. The wafer support structure of claim 8, wherein the thermal insulator is an inert gas.

10. The wafer support structure of claim 8, wherein the thermal insulator is selected from the group consisting of nitrogen, boron, argon, neon, and helium.

11. The wafer support structure of claim 8, wherein the protrusion extends from the second radius to a third radius along the top surface of the ring, wherein the third radius is larger than and concentric with the second radius of the ring, and the third radius is smaller than the outer radius.

12. A wafer support structure comprising:
a circular ring substantially circumscribing a circular cavity and generally concentric with the circular cavity and, wherein the circular ring comprises:
an inner radius immediately circumscribing the circular cavity;
an outer radius circumscribing the ring;
a bottom surface having portions substantially perpendicular to the axis of the ring;
a thermal insulator proximate to at least a portion of the bottom surface of the ring; and
a top surface having portions substantially perpendicular to the axis of the ring and substantially parallel to the bottom surface, and disposed opposite the bottom surface, wherein the top surface comprises a wafer facing surface extending circularly around the ring from the inner radius of the ring to a second radius, and perpendicular to the axis of the ring, wherein the second radius is larger than and concentric with the inner radius of the ring, and the second radius is smaller than the outer radius.

13. The wafer support structure of claim 12, further comprising a plurality of thermal insulators proximate to at least a portion of the bottom surface of the ring.

14. The wafer support structure of claim 12, wherein the top surface comprises a protrusion from the top surface extending around the ring, protruding, substantially parallel to the axis of the ring, and adjacent to the second radius.

15. The wafer support structure of claim 12, wherein the insulator is an inert gas.

16. The wafer support structure of claim 12, wherein the insulator is selected from the group consisting of nitrogen, boron, argon, neon, and helium.

17. A wafer support structure comprising:
a circular ring substantially circumscribing a circular cavity and generally concentric with the circular cavity and, wherein the circular ring comprises:
an inner radius immediately circumscribing the circular cavity;
an outer radius circumscribing the ring;
a bottom surface having portions substantially perpendicular to the axis of the ring;
a thermal insulator proximate to at least a portion of the bottom surface of the ring; and
a top surface having portions substantially perpendicular to the axis of the ring and substantially parallel to the bottom surface, and disposed opposite the bottom surface, wherein the top surface comprises:
a wafer facing surface extending circularly around the ring from the inner radius of the ring to a second radius, and perpendicular to the axis of the ring, wherein the second radius is larger than and concentric with the inner radius of the ring, and the second radius is smaller than the outer radius; and
a protrusion from the top surface extending around the ring, protruding in a direction substantially parallel to the axis of the ring, and adjacent to the second radius.

18. A wafer processing system comprising:
a housing defining a process chamber;
a high-density plasma generating system operatively coupled to the process chamber;
a gas-delivery system configured to introduce gases into the process chamber;
a pressure-control system for maintaining a selected pressure within the process chamber; and
a wafer support member comprising a circular ring substantially circumscribing a circular cavity and generally concentric with the circular cavity and, wherein the circular ring comprises:
an inner radius immediately circumscribing the circular cavity;
an outer radius circumscribing the ring;
a bottom surface having portions substantially perpendicular to the axis of the ring; and
a top surface having portions substantially perpendicular to the axis of the ring and substantially parallel to the bottom surface, and disposed opposite the bottom surface, wherein the top surface comprises:
a wafer facing surface extending circularly around the ring from the inner radius of the ring to a second radius, and perpendicular to the axis of the ring, wherein the second radius is larger than and concentric with the inner radius of the ring, and the second radius is smaller than the outer radius; and
a protrusion from the top surface extending around the ring, protruding in a direction substantially parallel to the axis of the ring, and adjacent to the second radius.

19. A wafer processing system comprising:
a housing defining a process chamber;
a high-density plasma generating system operatively coupled to the process chamber;
a gas-delivery system configured to introduce gases into the process chamber;
a pressure-control system for maintaining a selected pressure within the process chamber; and
a wafer support member comprising a circular ring substantially circumscribing a circular cavity and generally concentric with the circular cavity and, wherein the circular ring comprises:
an inner radius immediately circumscribing the circular cavity;
an outer radius circumscribing the ring;
a bottom surface having portions substantially perpendicular to the axis of the ring;
a thermal insulator proximate to at least a portion of the bottom surface of the ring; and
a top surface having portions substantially perpendicular to the axis of the ring and substantially parallel to the bottom surface, and disposed opposite the bottom surface, wherein the top surface comprises a wafer facing surface extending circularly around the ring from the inner radius of the ring to a second radius, and perpendicular to the axis of the ring, wherein the second radius is larger than and concentric with the inner radius of the ring, and the second radius is smaller than the outer radius.
